(19) United States
(12) Patent Application Publication
(10) Pub. No.: US 2025/0379040 A1
(43) Pub. Date: Dec. 11, 2025

(54) GAS DISTRIBUTION ASSEMBLY AND METHOD OF USING SAME

(71) Applicant: ASM IP Holding B.V., Almere (NL)

(72) Inventors: Yukihiro Mori, Tokyo (JP); Vincent Hubert Bernard Gilles Babin, Tokyo (JP); Naoto Tsuji, Tokyo (JP)

(21) Appl. No.: 19/312,840

(22) Filed: Aug. 28, 2025

Related U.S. Application Data
(62) Division of application No. 17/171,793, filed on Feb. 9, 2021, now Pat. No. 12,431,334.
(60) Provisional application No. 62/976,287, filed on Feb. 13, 2020.

(51) Int. Cl. H01J 37/32; C23C 16/455

(52) U.S. Cl. CPC H01J 37/32449; C23C 16/45536; C23C 16/45565; C23C 16/45582; C23C 16/45585; H01J 37/32091; H01J 37/32513; H01J 37/32568

(57) ABSTRACT

A gas distribution assembly and methods for adjusting the gas flow through a gas supply unit into a reaction chamber are disclosed. The gas distribution assembly and methods can be used to increase or decrease gas flow uniformly through the gas supply unit. The gas distribution assembly and methods can also be used to increase gas flow into one area of the reaction chamber, while decreasing gas flow into another area.

### CROSS-REFERENCE TO RELATED APPLICATIONS

This application is a divisional of application Ser. No. 17/171,793, filed Feb. 9, 2021 and titled GAS DISTRIBUTION ASSEMBLY AND METHOD OF USING SAME, which claims the benefit of and priority to U.S. Provisional Application No. 62/976,287, filed on Feb. 13, 2020 in the United States Patent and Trademark Office, the disclosures of which are incorporated herein in their entirety by reference.

### FIELD OF INVENTION

The present disclosure generally relates to an apparatus for adjusting the gas flow through a gas supply unit into a reaction chamber and methods of its use.

### BACKGROUND OF THE DISCLOSURE

Gas-phase reactors, such as chemical vapor deposition (CVD), plasma-enhanced CVD (PECVD), atomic layer deposition (ALD), and the like can be used for a variety of applications, including cleaning, depositing and etching materials on a substrate surface. For example, gas-phase reactors can be used to clean, deposit and/or etch layers on a substrate to form semiconductor devices, flat panel display devices, photovoltaic devices, microelectromechanical systems (MEMS), and the like.

For plasma processes, changing a gap between a shower plate and a gas channel changes the conductance of the gas into the shower plate, which can affect the profile of film deposition. However, changing a gap generally requires the design and manufacture of a new gas channel, as well as the replacement of the gas channel, which requires the following steps: bringing the reaction chamber back to atmospheric pressure, cooling the chamber down, disassembling the showerhead, replacing the gas channel, reassembling the showerhead, heating up the reaction chamber, and bringing the reaction chamber to low pressure. All of these steps take time and cost money, which greatly impacts the efficiency of the equipment. Moreover, when the deposited film thickness is uneven due to an unexpected cause such as a defect in the alignment of the parts constituting the equipment.

Plasma processes can be further influenced by a design of the shower plate. For example, the diameter, shape, number, and distribution pattern of holes in the shower plate may be adjusted in order to obtain desired controllability. However, manipulating any of these parameters generally includes use of different shower plates and the time consuming and expensive steps recited above in order to remove and replace the shower plates them for different conditions.

Therefore, improved apparatuses, assemblies, systems, and methods that provide improved gas distribution control, are desired.

Any discussion of problems and solutions set forth in this section has been included in this disclosure solely for the purposes of providing a context for the present disclosure, and should not be taken as an admission that any or all of the discussion was known at the time the invention was made.

### SUMMARY OF THE DISCLOSURE

Exemplary embodiments of this disclosure provide an apparatus and method for adjusting the distribution of a gas into a reaction chamber. While the ways in which various embodiments of the present disclosure address drawbacks of prior apparatuses and methods are discussed in more detail below, in general, various embodiments of the disclosure provide gas distribution assemblies and methods that can be used to adjust the amount of gas that is distributed from a showerhead to a reaction chamber.

In various embodiments of the disclosure, a gas distribution assembly comprises a gas manifold, a gas channel below the gas manifold, a shower plate assembly below the gas channel and in fluid communication with the gas manifold, and one or more adjustable gap devices; wherein a gap is formed between a lower surface of the gas channel and an upper surface of the shower plate assembly; and wherein the adjustable gap devices are configured to move the gas channel relative to the shower plate assembly, thereby adjusting the size of the gap.

The adjustable gap devices may be configured to move the gas channel in a vertical direction and/or tilt the gas channel relative to the shower plate assembly. The adjustable gap devices may be configured to be adjusted manually or remotely. Each of the one or more of the adjustable gap devices may be adjusted independently. In some embodiments, three or more adjustable gap devices are used. The adjustable gap device may be a screw, a bolt, or any other adjustment device. The adjustable gap device may further comprise a support ring having a larger surface area than a top surface of the adjustable gap device, wherein the upper surface of the support ring contacts the lower surface of the gas channel.

A central portion of the gas channel may be disposed within a central portion of the shower plate assembly. The gas distribution assembly may further comprise one or more sealing structures positioned between an outer lateral surface of the central portion of the gas channel and an inner lateral surface of the central portion of the shower plate assembly for preventing or mitigating gas leakage from the gap. The gas distribution assembly may also comprise one or more contact springs positioned between the outer lateral surface of the central portion of the gas channel and the inner lateral surface of the central portion of the shower plate assembly for electrically coupling the shower plate assembly to a power source.

The gas distribution assembly may further comprise an insulator below the gas manifold, and an adaptor between the gas manifold and the insulator, wherein the insulator is configured to move cooperatively with the gas channel. The gas distribution assembly may further include sealing structures between the adaptor and the insulator to mitigate gas leakage from the adaptor and the insulator.

In various embodiments, the shower plate assembly comprises an upper plate, a lower plate comprising a plurality of apertures, and one or more connectors that couple the upper plate to the lower plate; wherein the one or more connectors are configured to move at least one of the lower plate and the upper plate, thereby adjusting the size of the gap. The shower plate assembly may be used with the above described gas distribution assembly or with another gas distribution assembly. In some embodiments, the shower plate assembly further comprises a sealing structure between the upper plate and the lower plate. In some embodiments, the upper plate comprises a recess that receives an extension of the lower plate, and the connector connects the upper plate and lower plate at the location of the recess and the extension.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIGS. 1A and 1B illustrates a gas distribution assembly in accordance with at least one embodiment of the disclosure.

FIGS. 2A and 2B illustrate a gas distribution assembly in accordance with at least one embodiment of the disclosure.

FIG. 3 illustrates a gas distribution assembly in accordance with at least one embodiment of the disclosure.

FIG. 4 illustrates a pin device.

FIG. 5 illustrates an adjustable gap device in accordance with at least one embodiment of the disclosure.

FIG. 6 illustrates a gas manifold and insulator.

FIG. 7 illustrates a gas manifold, an adaptor, and an insulator in accordance with at least one embodiment of the disclosure.

FIG. 8 illustrates a shower plate assembly.

FIG. 9 illustrates a portion of a shower plate assembly in accordance with at least one embodiment of the disclosure.

FIG. 10 illustrates a portion of a shower plate assembly in accordance with at least one embodiment of the disclosure.

FIG. 11 illustrates a portion of a shower plate assembly in accordance with at least one embodiment of the disclosure.

FIG. 12 illustrates a portion of a reaction chamber in accordance with at least one embodiment of the disclosure.

FIG. 13 illustrates thickness profiles of silicon oxide deposited according to embodiments of the disclosure.

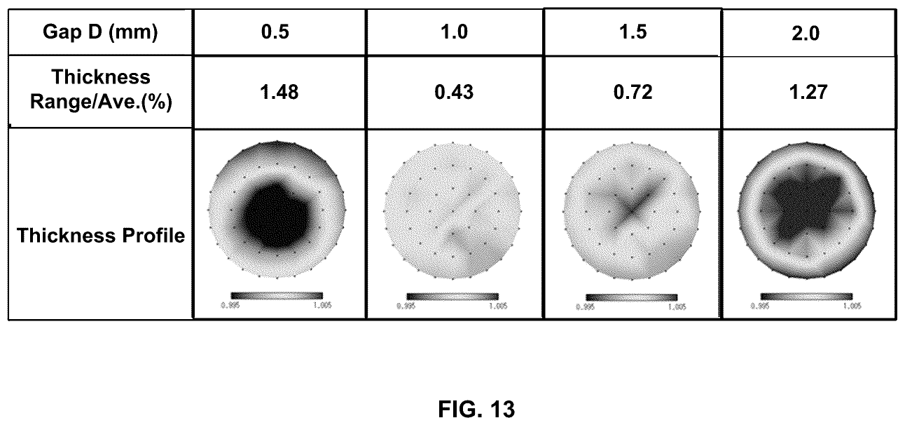

FIG. 14 illustrates a gas manifold, an adaptor, an insulator, and an RF cover in accordance with at least one embodiment of the disclosure.

FIG. 15 illustrates an adjustable gap device in accordance with at least one embodiment of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses described herein and obvious modifications and equivalents thereof. Thus, it is intended that the scope of the invention disclosed should not be limited by the particular disclosed embodiments described below.

The present disclosure generally relates to apparatuses, assemblies, and systems that include a gas distribution assembly and/or a shower plate assembly, and to methods of using same. As set forth in more detail below, exemplary systems, assemblies, apparatus, and methods described herein can be used to modify the gas flow distribution from a gas channel, through a gas supply unit, to a reaction chamber of a reactor for, for example, improved deposition uniformity. Additionally, or alternatively, the gas flow distribution from the gas channel to the reaction chamber can be manipulated in a relatively short amount of time and/or relatively inexpensively.

In this disclosure, “gas” can include material that is a gas at normal temperature and pressure, a vaporized solid and/or a vaporized liquid, and may be constituted by a single gas or a mixture of gases, depending on the context. A gas other than the process gas, i.e., a gas introduced without passing through a gas supply unit, such as a showerhead, other gas distribution device, or the like, may be used for, e.g., sealing the reaction space, and can include a seal gas, such as a rare gas. A gas can be a reactant or precursor that takes part in a reaction within a reaction chamber and/or include ambient gas, such as air.

In this disclosure, any two numbers of a variable can constitute a workable range of the variable as the workable range can be determined based on routine work, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “constituted by,” “including,” “include,” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

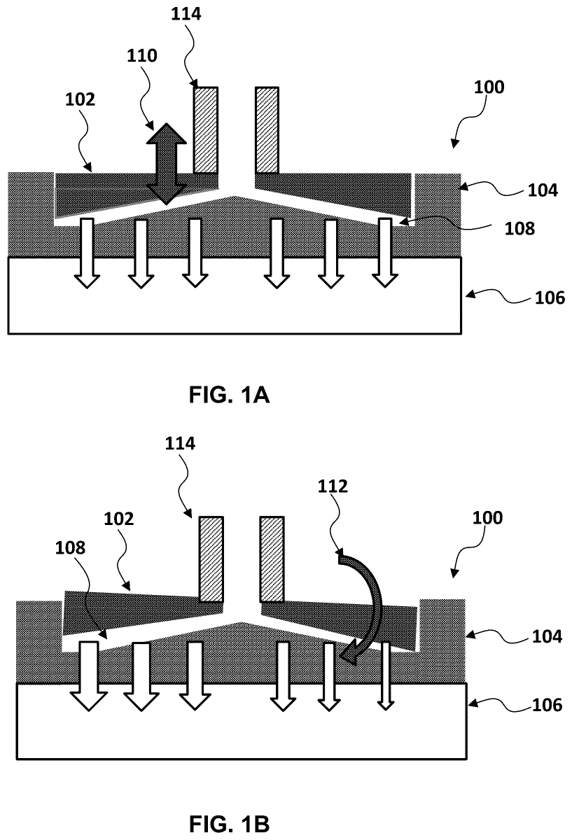

Turning to the figures, FIGS. 1A and 1B illustrate a gas distribution assembly 100 in accordance with at least one embodiment of the disclosure. Gas distribution assembly 100 includes a gas manifold 114, a gas channel 102, and a shower plate assembly 104. FIG. 1A illustrates the vertical movement 110 of gas channel 102 relative to shower plate 104, where the area between the lower surface of gas channel 102 and the upper surface of shower plate 104 defines a gap 108. As gas channel 102 moves up, the height of gap 108, defined between the lower surface of gas channel 102 and the upper surface of shower plate 104, increases. As gas channel 102 moves down, the height of gap 108 decreases. FIG. 1B illustrate the tilting movement 112 of gas channel 102. The white arrows illustrate the amount of gas flow through shower plate 104 into reaction chamber 106, as affected by the size of gap 108 which can change with the vertical movement and tilt of gas channel 102. Wider arrows indicate higher gas flow, and more narrow arrows indicate lower gas flow. As illustrated in FIG. 1B, as gas channel 102 tilts downward at one location of the assembly 100, gas flow through shower plate 104 and into reaction chamber 106 is reduced at that location. The tilting movement can lift gas channel 102 upward at other areas of the assembly, causing gas flow to increase at those areas.

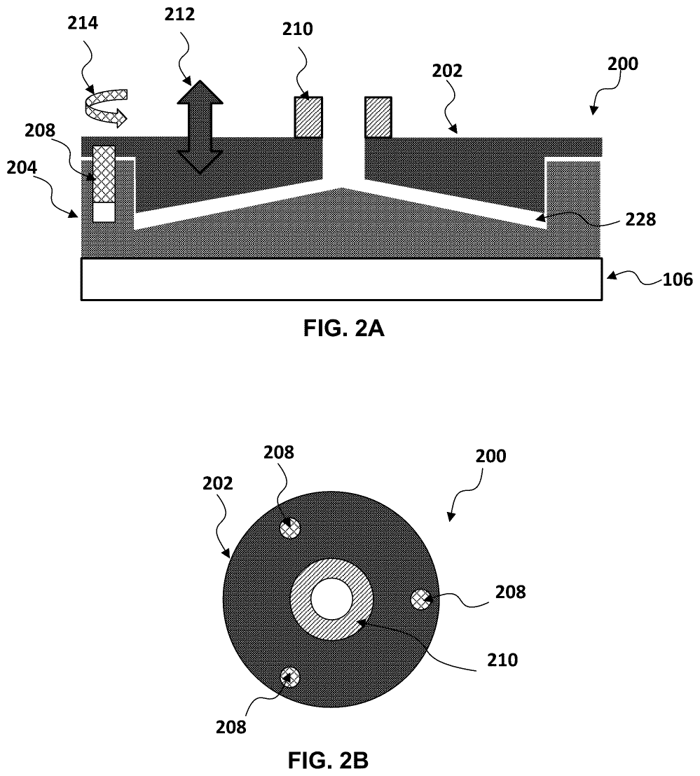

FIGS. 2A and 2B illustrate a gas distribution assembly 200 in accordance with at least one embodiment of the disclosure. In the illustrated example, assembly 200 includes gas channel 202, shower plate assembly 204, adjustable gap devices 208, and gas manifold 210. FIG. 2A illustrates the vertical movement 212 of gas channel 202 relative to shower plate 204, as adjustable gap device 208 is rotated 214 according to some embodiments. The vertical movement changes the size of gap 228. FIG. 2B illustrates a top view of gas distribution assembly 200, where three approximately evenly spaced adjustable gap devices 208 are visible. In the illustrated embodiment, gas distribution assembly 200 includes three adjustable gap devices 208 that are spaced apart by approximately 120°. In this context, “approximately” means within plus or minus 10 degrees. In other embodiments, gas distribution assembly 200 includes one adjustable gap device 208. In other embodiments, gas distribution assembly 200 includes two adjustable gap devices 208. In still other embodiments, gas distribution assembly 200 includes several adjustable gap devices 208, e.g. four, five, six, seven, eight, nine, ten, etc. gap devices, which can be, for example, evenly spaced apart.

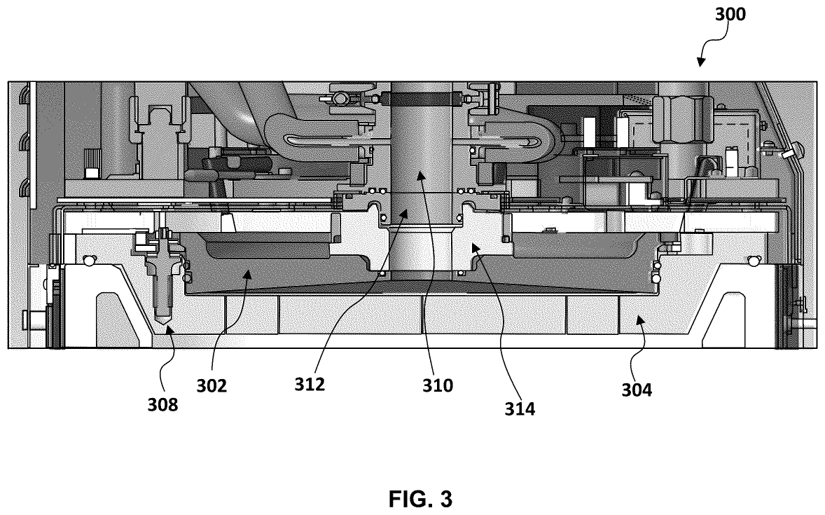

FIG. 3 illustrates a gas distribution assembly 300 according to an embodiment of the present disclosure. Gas distribution assembly 300 includes adjustable gap device 308, and further includes an adaptor 312. As adjustable gap device 308 is used to adjust the vertical movement and/or tilt of gas channel 302 relative to shower plate assembly 304, adaptor 312 allows insulator 314 to move without impacting gas manifold 310.

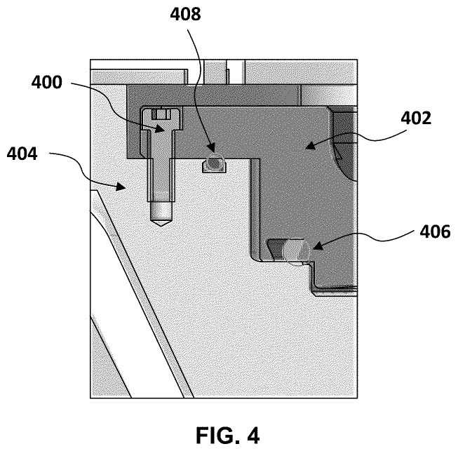

FIG. 4A illustrates a portion of a gas distribution assembly that uses a fixed pin 400 to fix a gap distance. As illustrated, pin 400 passes through shower plate assembly 404 and gas channel 402, and is not adjustable, therefore the gap is not adjustable without disassembly of the gas distribution assembly. Sealing structure 406 is placed between the lower surface of gas channel 402 and the upper surface of shower plate assembly 404 in order to prevent or mitigate gas leakage. Contact spring 408, located between the lower surface of gas channel 402 and the upper surface of shower plate assembly 404, permits RF propagation from a power source through shower plate assembly 404.

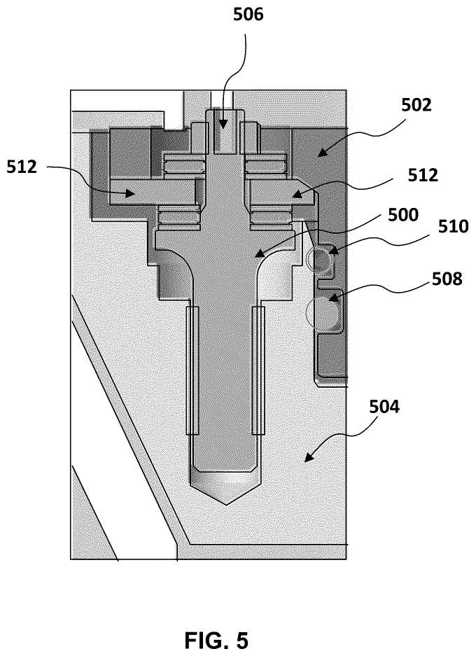

An exemplary adjustable gap device 500 in accordance with the present disclosure is illustrated in greater detail in FIG. 5. In contrast to pins previously used in gas distribution assemblies, such as pin 400, adjustable gap device 500 is capable of being adjusted to raise or lower gas channel 502 relative to shower plate assembly 504. In some embodiments, adjustable gap device 500 is a screw. However, any adjustment device or mechanism, such as a threaded adjustment device; e.g. a bolt, moveable shim, or the like can be used. When adjustable gap device 500 is a screw, adjustable gap device 500 or similar device may include, e.g., a hexagonal recess 506 for receiving a wrench key that can be used to rotate the screw. However, any type of screw and corresponding adjustment device may be used. In contrast to previous gas distribution assemblies, sealing structure 508 and contact spring 510 are placed laterally between the outer surface of gas channel 502 and inner surface of shower plate assembly 504. This can reduce or mitigate displacement of the sealing structure 508 and contact spring 510 as gas channel 502 moves, thereby maintaining vacuum conditions and RF propagation. In some embodiments, sealing structure 508 is an O-ring. However, any sealing device may be used. In some embodiments, one or more of adjustable gap devices 500 are adjustable from outside of the reactor. In some embodiments, one or more of adjustable gap devices 500 are adjustable manually. In some embodiments, one or more of adjustable gap devices 500 are adjustable remotely.

When gas channel 502 is supported by a lower number of adjustable gap devices 500, e.g. three or less, a high constraint concentration can occur at the locations of the adjustable gap devices 500. If adjustable gap device 500 is made of a material that cannot resist the constraint, damage to the device might occur. Therefore, in some embodiments, support ring 512 is added to widen the contact area between adjustable gap device 500 and the lower surface of gas channel 502. In some embodiments, support ring 512 is made of a strong alloy, such as carbon steels, chrome molybdenum steels, etc. In some embodiments, spring (not shown) may be added to support the gas channel and diminish the force resulting on the adjustable gap devices 500.

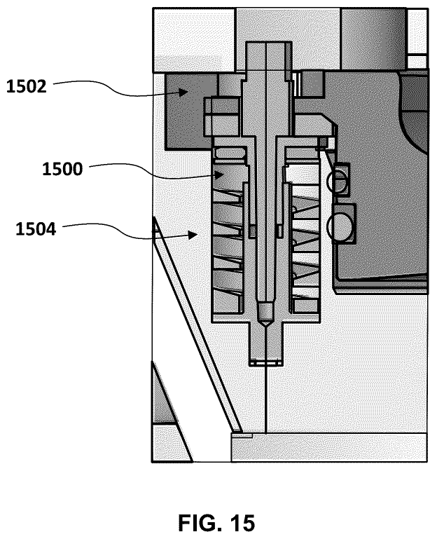

In another embodiment, the constraint concentration is reduced using one or more springs 1500, as illustrated in FIG. 15. Spring 1500 may be added to prevent or reduce damage to gas channel 1502 and shower plate assembly 1504. In some embodiments, one spring 1500 is used. In some embodiments, several springs 1500 are used, e.g. two, three, four, five, six, seven, eight, nine, ten, etc. springs, which can be, for example, evenly spaced apart.

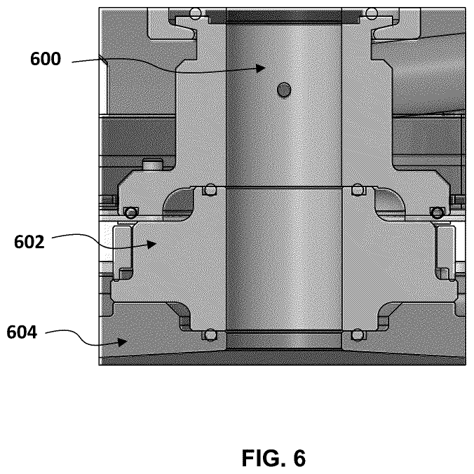

An example of a gas manifold 600 and insulator 602 are shown in FIG. 6. In previous gas distribution assemblies, the gas manifold 600 and insulator 602 are fixed. Gas channel 604 is not moved and has no impact on the other parts.

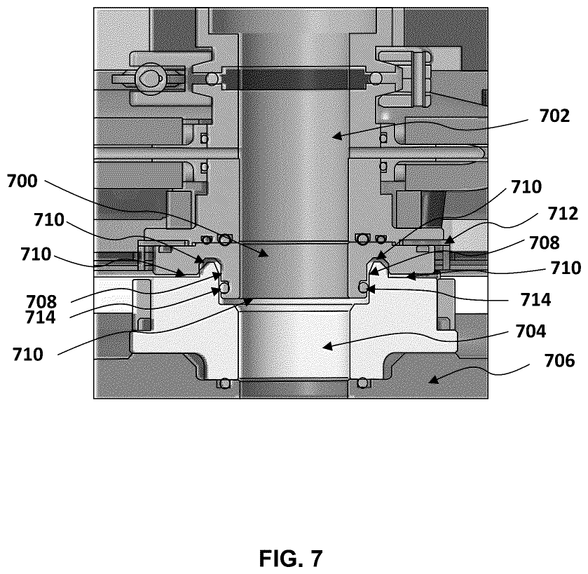

In contrast, some embodiments of the present disclosure include an adaptor 700, as illustrated in FIG. 7. In some embodiments, adaptor 700 is fixed to gas manifold 702, and is placed between gas manifold 702 and insulator 704. Further, in contrast to manifolds previously used in gas distribution assemblies, insulator 704 is not fixed. Rather, insulator 704 can move, e.g., cooperatively with the vertical movement and tilt of gas channel 706. In some embodiments, horizontal gaps 708 allow insulator 704 to shift in a horizontal direction as gas channel 706 tilts. In some embodiments, vertical gaps 710 allow insulator 704 to shift in a vertical direction as gas channel 706 moves vertically. In some embodiments, adaptor sealing structures 714 are used to mitigate or prevent gas leakage from the vertical and horizontal gaps.

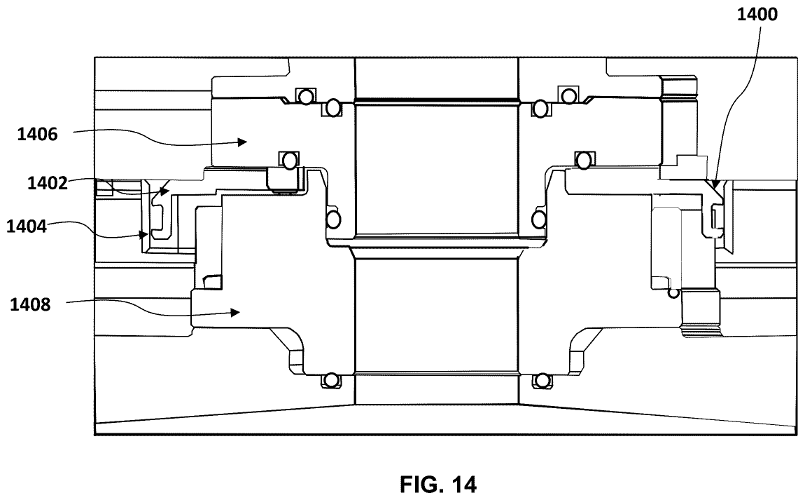

In some embodiments, RF cover 712 is a unitary design. However, RF cover may include two or more parts. FIG. 14 illustrates another exemplary RF cover 1400. In this embodiment, RF cover 1400 is split into two parts, an interior part 1402 and an exterior part 1404. The interior part surrounds adaptor 1406 and insulator 1408. In some embodiments, the two parts have contact springs between them to allow the RF to flow through the parts.

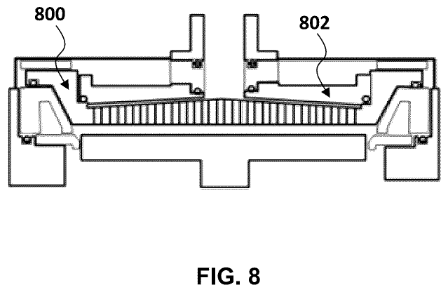

In some embodiments, the shower plate assembly is also adjustable to control gas flow into the reaction chamber. FIG. 8 illustrates a shower plate 800 where shower plate 800 is a single plate that receives gas channel 802.

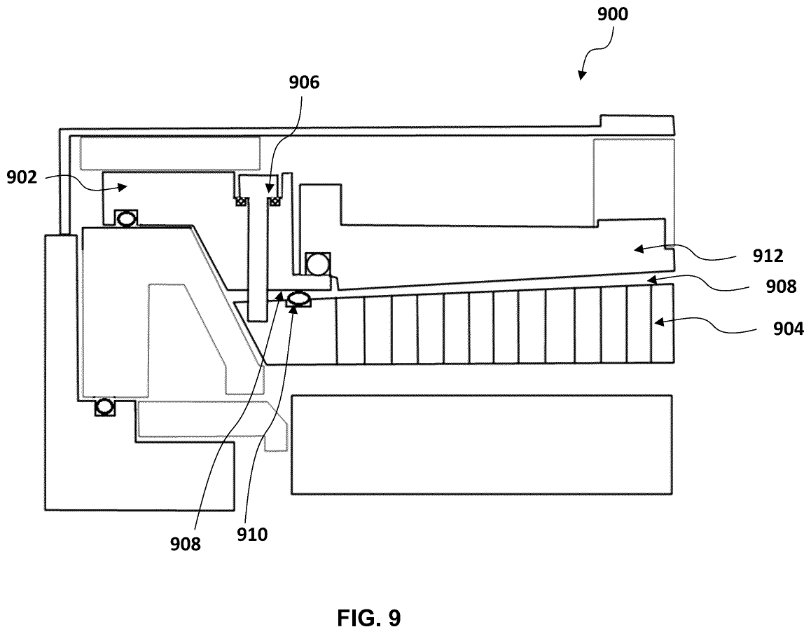

FIG. 9 illustrates a portion of shower plate assembly 900 according to an embodiment of the present disclosure. Shower plate assembly 900 comprises an upper plate 902, a lower plate 904, and one or more connectors 906 that couple upper plate 902 to lower plate 904. A gap 908 is formed between the lower surface of upper plate 902 and gas channel 912, and the upper surface of lower plate 904. Connectors 906 are adjustable for controlling the size of gap 908 and therefore the amount of gas flow from gas channel 912 into lower plate 904. In some embodiments, adjusting connectors 906 moves lower plate 904 in a vertical direction relative to upper plate 902. In some embodiments, adjusting connectors 906 moves upper plate 902 in a vertical direction relative to lower plate 904. In other embodiments, adjusting connectors 906 moves upper plate 902 and lower plate 904 in opposite directions to adjust the size of gap 908.

Similar to the adjustable gap device described above, in some embodiments connector 906 is a screw. However, any fastening device that can be used to adjust the size of a gap between upper plate 902 and lower plate 904 can be used. In some embodiments, shower plate assembly 900 includes two connectors 906. However, shower plate assembly 900 can include several connectors 906, e.g. three, four, five, six, seven, eight, nine, ten, etc. connectors 906.

In some embodiments, shower plate assembly 900 includes one or more sealing devices 910 configured to mitigate or prevent gas leakage from gap 908. In some embodiments, one sealing device 910 is used at each connector 906. In other embodiments, two sealing devices 910 are used, one proximate to connector 906 at an inner portion of upper plate 902 and lower plate 904, the other proximate to connector 906 at an outer portion of upper plate 902 and lower plate 904.

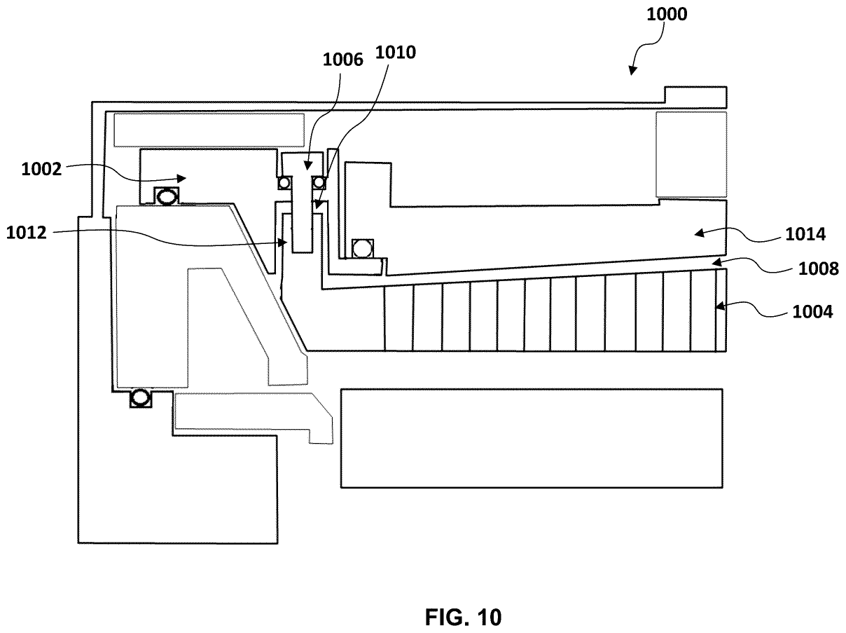

FIG. 10 illustrates a portion of another exemplary shower plate assembly 1000. In this embodiment, shower plate assembly 1000 comprises upper plate 1002, lower plate 1004, and one or more connectors 1006, where gas leakage from gap 1008 is reduced or prevented in the absence of a sealing device. In some embodiments, a recess 1010 near the outer edge of upper plate 1002 is configured to receive an extension 1012 of lower plate 1004. This configuration creates an elevated segment of gap 1008, which connector 1006 passes through. This configuration reduces gas leakage from gap 1008 as the gas passes from gas channel 1014 to lower plate 1004.

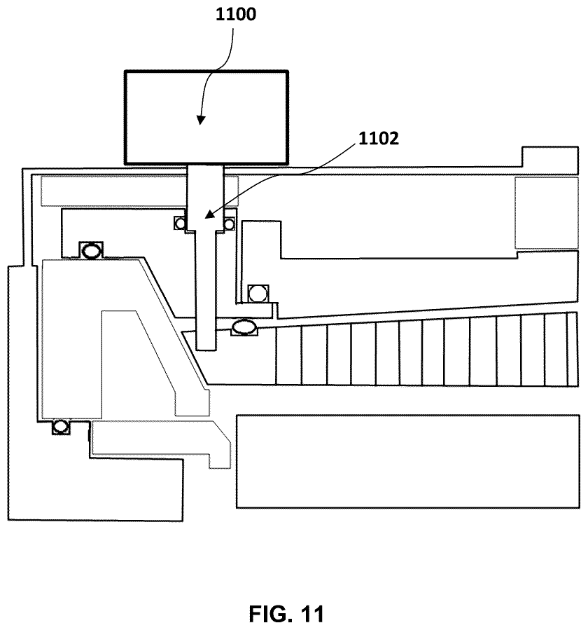

In some embodiments, one or more of connectors 906/1006 are adjustable from outside of the reactor. In some embodiments, one or more of connectors 906/1006 are adjustable manually. In some embodiments, one or more of connectors 906/1006 are adjustable remotely. As illustrated in FIG. 11, in some embodiments one or more of connectors 1102 are adjusted via stepping motor 1100 installed outside of the reactor and is operatively coupled to one or more connectors 906/1006.

### Example 1

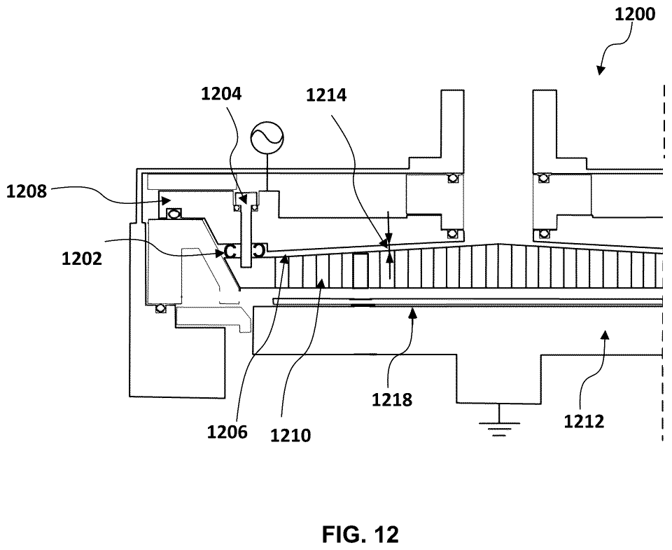

FIG. 12 illustrates a portion of the reaction chamber that was used to perform silicon oxide film depositions on a 300 mm Si substrate by a plasma ALD process. The reaction chamber 1200 has two metal sealing structures, e.g. O-rings 1202 (inner and outer) adjacent to connector 1204. The O-rings are made of inconel 600 alloy and have a C-shaped cross-section. The O-rings have a cross-sectional diameter of 8 mm and a spring characteristic. The O-rings are used within an elastic deformation margin for adjustment of gap 1206. Additionally, the surface is coated with aluminum to enable good seal capability, heavy metal contamination prevention, and preferable permeability for an RF power transmission from upper plate 1208 to lower plate 1210. The diameter of the substrate susceptor 1212 is 325 mm, and the diameter of lower plate 1210 is 350 mm. 200 W RF power (13.56 MHz) was applied on upper plate 1208, and the susceptor 1212 was earth grounded. Substrate 1218 was placed on substrate susceptor 1212, and the distance 1214 between lower plate 1210 and gas channel 1216 was adjusted using connector(s) 1204.

FIG. 12 shows process performances with the reaction chamber 900. The susceptor temperature was controlled at 100° C., and the reactor pressure was set at 400 Pa. The gap 1206 between upper plate 1208 and lower plate 1210 was adjusted from 0.5 mm to 2.0 mm. The gap 1206 between the two plates effectively controlled the film thickness profile. A narrower gap between the two plates yielded a concave film profile, wherein the center was thin. The wider gap yielded a convex film profile, wherein the center was thick.

Any of the above described shower plate assemblies can be used in any of the above described gas distribution assemblies. Alternatively, shower plate assembly can be used in other assemblies.

In some embodiments, a method is provided for adjusting the conductance of a gas into a reaction chamber using one or more of the above described gas distribution assemblies and shower plate assemblies.

The example embodiments of the disclosure described above do not limit the scope of the invention since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A gas distribution assembly for distributing a gas to a reaction chamber comprising:
a gas manifold;
a gas channel below the gas manifold; and
a shower plate assembly below the gas channel and in fluid communication with the gas manifold,
wherein the gas channel is configured to tilt relative to the shower plate assembly, and
wherein in response to the gas channel tilting, a flow of gas through the shower plate assembly proximate a first portion of the shower plate assembly is configured to be reduced.

2. The gas distribution assembly of claim 1, wherein in response to the gas channel tilting, a flow of gas through the shower plate assembly proximate a second portion of the shower plate assembly is configured to be increased.

3. The gas distribution assembly of claim 1, further comprising one or more adjustable gap devices interposed between and mechanically coupled to the gas channel and the shower plate assembly.

4. The gas distribution assembly of claim 3, wherein the one or more adjustable gap devices are configured to cause the gas channel to tilt relative to the shower plate assembly.

5. The gas distribution assembly of claim 3, wherein the one or more adjustable gap devices are configured to be adjusted independently.

6. The gas distribution assembly of claim 1, wherein the shower plate assembly comprises a plate comprising a plurality of apertures, the plurality of apertures extending from an upper surface of the plate to a lower surface of the plate.

7. The gas distribution assembly of claim 6, wherein a thickness of the shower plate assembly is greater at a center of the shower plate assembly than at an edge of the shower plate assembly.

8. The gas distribution assembly of claim 1, wherein a gap is formed between a lower surface of the gas channel and an upper surface of the shower plate assembly.

9. The gas distribution assembly of claim 8, wherein in response to the gas channel tilting, a size of the gap is changed.

10. A gas distribution assembly for distributing a gas to a reaction chamber comprising:
a gas manifold;
a gas channel below the gas manifold;
a shower plate assembly below the gas channel and in fluid communication with the gas manifold;
an insulator between the gas manifold and the gas channel; and
an adaptor between the insulator and the gas manifold,
wherein the gas channel is configured to move relative to the shower plate assembly, and
wherein the adaptor is configured to allow the insulator to move in response to the gas channel moving without impacting the gas manifold.

11. The gas distribution assembly of claim 10, wherein the adaptor is fixedly coupled to the gas manifold.

12. The gas distribution assembly of claim 10, wherein the insulator is movably coupled to the adaptor.

13. The gas distribution assembly of claim 12, wherein the insulator is configured to move cooperatively with a movement of the gas channel.

14. The gas distribution assembly of claim 10, further comprising a plurality of horizontal gaps disposed between a portion of the insulator and a portion of the adaptor.

15. The gas distribution assembly of claim 14, wherein the plurality of horizontal gaps are configured to accommodate a horizontal shift of the insulator in response to a movement of the gas channel.

16. The gas distribution assembly of claim 14, further comprising a plurality of sealing structures disposed within the plurality of horizontal gaps, the plurality of sealing structures configured to prevent gas flow through the plurality of horizontal gaps.

17. The gas distribution assembly of claim 10, further comprising a plurality of vertical gaps disposed between a portion of the insulator and a portion of the adaptor.

18. The gas distribution assembly of claim 17, wherein the plurality of vertical gaps are configured to accommodate a vertical shift of the insulator in response to a movement of the gas channel.

19. The gas distribution assembly of claim 17, further comprising a plurality of sealing structures disposed within the plurality of vertical gaps, the plurality of sealing structures configured to prevent gas flow through the plurality of vertical gaps.

20. A gas distribution assembly for distributing a gas to a reaction chamber comprising:
a gas manifold;
a gas channel below the gas manifold;
a shower plate assembly below the gas channel and in fluid communication with the gas manifold;
an insulator between the gas manifold and the gas channel; and
an adaptor between the insulator and the gas manifold,
wherein the gas channel is configured to tilt relative to the shower plate assembly,
wherein in response to the gas channel tilting, a flow of gas through the shower plate assembly proximate a first portion of the shower plate assembly is configured to be reduced, and
wherein the adaptor is configured to allow the insulator to move in response to the gas channel moving without impacting the gas manifold.
